(19) United States
(12) Patent Application Publication
(10) Pub. No.: US 2026/0167030 A1
(43) Pub. Date: Jun. 18, 2026

(54) Cooling System for Electric Vehicle Charging Heat Loads

(71) Applicant: ChargePoint, Inc., Campbell, CA (US)

(72) Inventors: Hossein Kazemi, San Francisco, CA (US); Dennis Michael Heleine, Morgan Hill, CA (US); Shishir Sirohi, Mountain View, CA (US)

(21) Appl. No.: 19/423,814

(22) Filed: Dec. 17, 2025

Related U.S. Application Data
(60) Provisional application No. 63/735,239, filed on Dec. 17, 2024.

(51) Int. Cl. B60L 53/302; B60L 53/16; B60L 53/18; H05K 7/20

(52) U.S. Cl. CPC B60L 53/302; B60L 53/16; B60L 53/18; H05K 7/20145; H05K 7/20154; H05K 7/20336; H05K 7/20436

(57) ABSTRACT

A cooling system for electric vehicle (EV) charging heat loads is described. The system includes a pressurized air system, such as a compressor or fans, that delivers ambient air. A charging cable transports this air through a cable feed tube to an EV charging cable connector. Within the cable, power conductors are concentrically placed inside finned tubes to create air gaps between the conductors and the tubes. The connector includes a manifold that directs the incoming ambient air over a set of charging contacts to cool them. The manifold then directs the air through the air gaps between the power conductors and their corresponding finned tubes, allowing the air to extract heat from the power conductors as it flows through the cable.

### CROSS-REFERENCE TO RELATED APPLICATIONS

This application claims the benefit of U.S. Provisional Application No. 63/735,239, filed Dec. 17, 2024, which is hereby incorporated by reference.

### FIELD

Embodiments of the invention relate to the field of electric vehicle (EV) charging systems; and more specifically to a cooling system for electric vehicle charging heat loads.

### BACKGROUND

EV charging plugs conventionally rely on natural air convection and thermal conduction along the copper conductor to transport and dissipate thermal loads generated in the contacts during a charging session. The only active solution is the use of a thermal liquid such as liquid to transport thermal energy from the charging plug to a thermal sink.

Natural convection is reliant on external environmental factors such as the external ambient temperature, wind speed, humidity, pollution/contaminants, and seasonal air currents to pull the energy from the plug. This makes natural convection highly inefficient and unpredictable, which leads to limiting performance of the charging system. Thermal conduction along the copper conductors is limited to ensure safe touch temperatures for the users and increasing copper in the charging cable makes the solution expensive, inefficient, and cumbersome for the user.

Liquid cooling systems are costly and need additional equipment such as a pump, radiator, fan, or even a chiller.

Charging cables generate heat when power is transferred from the charging station to the electric vehicle. Conventionally the heat is dissipated to the environment via natural convection (air flow over the outer jacket of the cable). Another conventional technique is to use liquid to dissipate the heat generated from the charging cable.

### SUMMARY

In some aspects, the techniques described herein relate to an electric vehicle (EV) charging cable connector attached to an EV charging cable, including: a set of one or more charging contacts; a manifold that is in contact with the set of one or more charging contacts and directs pressurized air received through a supply tube within the EV charging cable over the set of one or more charging contacts to create an airflow; a set of one or more air exhaust vents; and one or more vent channels to guide a hot side of the airflow through the set of one or more air exhaust vents. The set of one or more charging contacts may each include at least one radiative fin, where the radiative fin may be rectangular shaped, ring shaped, or y-shaped. The EV charging cable connector may further include: a heat sink; and one or more heat pipes directly connected to the set of one or more charging contacts, the one or more heat pipes to transfer heat from the set of one or more charging contacts to the heat sink. The EV charging cable connector may further include a heat sink; a thermal epoxy connected to the set of one or more charging contacts; one or more heat pipes connected to the thermal epoxy, the one or more heat pipes to transfer heat from the set of one or more charging contacts to the heat sink.

In some aspects, the techniques described herein relate to an electric vehicle (EV) charging cable connector attached to an EV charging cable, including: a set of one or more charging contacts; a set of one or more intake vents; a fan to draw air from the ambient environment through the set of one or more intake vents and cool the set of one or more charging contacts; a set of one or more air exhaust vents; and one or more vent channels to guide hot hair through the set of one or more air exhaust vents. The set of one or more charging contacts may each include at least one radiative fin, where the radiative fin may be rectangular shaped, ring shaped, or y-shaped. The EV charging cable connector may further include: a heat sink; and one or more heat pipes directly connected to the set of one or more charging contacts, the one or more heat pipes to transfer heat from the set of one or more charging contacts to the heat sink. The EV charging cable connector may further include: a heat sink; a thermal epoxy connected to the set of one or more charging contacts; one or more heat pipes connected to the thermal epoxy, the one or more heat pipes to transfer heat from the set of one or more charging contacts to the heat sink.

In some aspects, the techniques described herein relate to an electric vehicle (EV) charging cable connector attached to an EV charging cable, including: a set of one or more charging contacts; a set of one or more air exhaust vents; a thermoelectric device that when a voltage is applied generates a temperature gradient that removes heat from the set of one or more charging contacts, wherein a cold end of the thermoelectric device is attached to the set of one or more charging connector contacts via a thermal interface material, and wherein a hot end of the thermoelectric device is connected to a heat sink; and the heat sink to dissipate heat from the set of one or more charging contacts, the heat exiting the EV charging cable connector through the set of one or more air exhaust vents. The set of one or more charging contacts may each include at least one radiative fin, where the radiative fin may be rectangular shaped, ring shaped, or y-shaped. The EV charging cable connector may further include: a set of one or more fans that are connected to the heat sink and extract heat away from the heat sink towards the set of one or more air exhaust vents.

In some aspects, the techniques described herein relate to a cooling system for electric vehicle (EV) charging heat loads, including: a pressurized air system for delivering ambient air, the pressurized air system including at least one of a compressor system and a set one or more fans; a charging cable that includes: a plurality of power conductors, each concentrically placed inside a corresponding finned tube, thereby creating an air gap between each power conductor and its corresponding finned tube, and a cable feed tube that carries the ambient air from the pressurized air system to an EV charging cable connector attached to the charging cable to cool a set of one or more charging contacts; wherein the EV charging cable connector includes: the set of one or more charging contacts, and a manifold that directs the ambient air carried through the cable feed tube over the set of one or more charging contacts and through each air gap between each power conductor and its corresponding finned tube. The manifold may be in contact with the set of one or more charging contacts. The set of one or more charging contacts may each include at least one radiative fin, where the radiative fin may be rectangular shaped, ring shaped, or y-shaped. The EV charging cable connector may further include: a heat sink; and one or more heat pipes directly connected to the set of one or more charging contacts, the one or more heat pipes to transfer heat from the set of one or more charging contacts to the heat sink. The EV charging cable connector may further include: a heat sink; a thermal epoxy connected to the set of one or more charging contacts; and one or more heat pipes connected to the thermal epoxy, the one or more heat pipes to transfer heat from the set of one or more charging contacts to the heat sink.

In some aspects, the techniques described herein relate to a cooling system for electric vehicle (EV) charging heat loads, including: a sub-ambient cooling system for delivering sub-ambient refrigerant gas; a charging cable that includes: a plurality of power conductors, each concentrically placed inside a corresponding finned tube, thereby creating an air gap between each power conductor and its corresponding finned tube, and a cable feed tube that carries the sub-ambient refrigerant gas from the sub-ambient cooling system to an EV charging cable connector attached to the charging cable to cool a set of one or more charging contacts; wherein the EV charging cable connector includes: the set of one or more charging contacts, and a manifold that directs the sub-ambient refrigerant gas carried through the cable feed tube over the set of one or more charging contacts and through each air gap between each power conductor and its corresponding finned tube. The manifold may be in contact with the set of one or more charging contacts. The set of one or more charging contacts may each include at least one radiative fin, where the radiative fin may be rectangular shaped, ring shaped, or y-shaped. The EV charging cable connector may further include: a heat sink; and one or more heat pipes directly connected to the set of one or more charging contacts, the one or more heat pipes to transfer heat from the set of one or more charging contacts to the heat sink. The EV charging cable connector may further include: a heat sink; a thermal epoxy connected to the set of one or more charging contacts; and one or more heat pipes connected to the thermal epoxy, the one or more heat pipes to transfer heat from the set of one or more charging contacts to the heat sink. The sub-ambient refrigerant gas may be returned back to the sub-ambient cooling system.

In some aspects, the techniques described herein relate to a cooling system for electric vehicle (EV) charging heat loads, including: a heat exchanger that is integrated between a pressurized air system and a sub-ambient cooling system; the pressurized air system for delivering ambient air to the heat exchanger; the sub-ambient cooling system for delivering sub-ambient refrigerant gas to the heat exchanger, wherein the sub-ambient refrigerant gas cools the ambient air delivered by the pressurized air system to sub-ambient air; a charging cable that includes: a plurality of power conductors, each concentrically placed inside a corresponding finned tube, thereby creating an air gap between each power conductor and its corresponding finned tube, and a cable feed tube that carries the sub-ambient air from the heat exchanger to an EV charging cable connector attached to the charging cable to cool a set of one or more charging contacts; and wherein the EV charging cable connector includes: the set of one or more charging contacts, and a manifold that directs the sub-ambient air carried through the cable feed tube over the set of one or more charging contacts and through each air gap between each power conductor and its corresponding finned tube. The manifold may be in contact with the set of one or more charging contacts. The set of one or more charging contacts may each include at least one radiative fin, where the radiative fin may be rectangular shaped, ring shaped, or y-shaped. The EV charging cable connector may further include: a heat sink; and one or more heat pipes directly connected to the set of one or more charging contacts, the one or more heat pipes to transfer heat from the set of one or more charging contacts to the heat sink. The EV charging cable connector may further include: a heat sink; a thermal epoxy connected to the set of one or more charging contacts; and one or more heat pipes connected to the thermal epoxy, the one or more heat pipes to transfer heat from the set of one or more charging contacts to the heat sink. The sub-ambient air may be vented to the atmosphere.

### BRIEF DESCRIPTION OF THE DRAWINGS

The invention may best be understood by referring to the following description and accompanying drawings that are used to illustrate embodiments of the invention. In the drawings:

FIG. 1 shows an air cooled EV charging cable connector according to an embodiment.

FIG. 2 shows an air cooled EV charging cable connector according to another embodiment.

FIG. 3 shows an air cooled EV charging cable connector according to another embodiment.

FIG. 4 shows examples of a charging contact with radiative fins according to an embodiment.

FIG. 5 illustrates an example heat pipe configuration according to an embodiment.

FIG. 6 illustrates another example heat pipe configuration according to an embodiment.

FIG. 7 shows an example thermoelectric device assembly according to an embodiment, which can be used in the embodiment shown in FIG. 3.

FIG. 8 shows a cross-section of an example charging cable 800 according to an embodiment.

FIG. 9 illustrates exemplary finned tube structures according to an embodiment.

FIG. 10 shows a system for cooling the charging cable using forced air, according to an embodiment.

FIG. 11 shows a system for cooling the charging cable using a sub-ambient cooling system, according to an embodiment.

FIG. 12 shows a system for cooling the charging cable where a heat exchanger is integrated between a sub-ambient cooling system and a forced air system to cool the charging cable, according to an embodiment.

FIG. 13 shows an exemplary embodiment of an electric vehicle supply equipment (EVSE) according to an embodiment.

### DESCRIPTION OF EMBODIMENTS

A cooling system for electric vehicle charging heat loads is described. In one aspect, an air cooled electric vehicle (EV) charging cable connector is described. The air-cooled EV charging cable connector enhances the performance of the EV cable connector by reducing the thermal load of the charging cable connector by enhancing heat exchange surfaces. In one aspect, an active air-cooled solution is used that uses forced convection heat transfer mechanism to remove heat from the charging cable connector and transfer the heat to a thermal sink. This aspect can use forced air to the charging cable connector to remove heat from the charging cable connector. Forced air may come from a fan either internal or external to the charging cable connector. The reduction of thermal load from the charging cable connector results in lower contact temperature and resistance. This allows delivery of higher charging currents from the charging cable connector and increases the overall performance of the charging cable connector.

In an embodiment, the forced air is delivered to the charging cable connector from a source that is external to the charging cable connector. A pressurized air supply, which may be supplied by an electric vehicle supply equipment (EVSE), feeds pressurized air through a feed tube to the thermal source (the charging cable connector). The pressurized air is fed to the EV cable connector through the charging cable. The air acts as an active thermal fluid which removes thermal load from the charging plug. This air picks up the heat load generated during a charging session and cools down the charge carrying components in the charging cable connector. The incoming air can be fed to the EV cable connector in different ways including: fed to a manifold directly in contact with the charging cable connector contact pins; fed to the charging cable connector cavity which is embedded with channels and fins to create flow paths for the air to permeate and remove heat by increasing surface area. After extracting heat, the hot air exits the charging cable connector and/or via the charging cable. For example, the hot air can exit through one or more return tubes in the charging cable and/or through one or more exit vents on the charging cable connector. The hot air carries away the thermal load generated in the charging cable connector thereby improving performance and efficiency. As another example, the hot air can exit through the power conductors of the charging cable via an air-gap in the power conductor tubes and/or through one or more exit vents on the charging cable connector.

In another embodiment, the forced air is delivered to the charging cable connector from a source that is internal to the charging cable connector. For example, a fan/rotary turbine can be included in the charging cable connector. The fan/rotary turbine may be powered from the EVSE. The fan/rotary turbine, when turned on, draws air inside the charging plug from the ambient environment. The air is drawn from the inlet vents of the charging cable connector. The air is channeled to the manifold that is coupled with the charging cable connector contact pins via micro-ducts to target the air and increase air velocity. The high velocity air extracts heat from the charge carrying components of the charging cable connector.

After extracting heat, the hot air exits the charging cable connector. For example, the hot air can exit through one or more exit vents on the charging cable connector. Additionally, or alternatively to exiting through exit vent(s), the hot air can exit through one or more return tubes in the charging cable, which can then be vented to the external environment via the EVSE. Additionally, or alternatively to exiting through exit vent(s), each power conductor within the charging cable can be placed inside its own finned tube concentrically to create an air-gap. Hot air can then be directed to flow through the air gap within each finned tube along the length of the charging cable, which can then be vented to the external environment via the EVSE.

In another embodiment, a Piezo electric material is incorporated into the charging cable connector. Upon application of a small electric power from the EVSE, it will create controlled vibrations that will generate air flow/currents inside the charging plug. The piezo electric material in combination with adequately designed vents allows removal of thermal load from the charging plug by leveraging forced convection heat transfer mechanism.

In another embodiment, a thermoelectric device is used to remove heat from the charging connector contacts. A voltage is applied to the thermoelectric device to generate a temperature gradient that removes heat from the charging connector contacts. The cold end of the thermoelectric device is attached to the charging connector contacts via a thermal interface material, and the hot end is connected to a heat sink. The heat sink is used to dissipate the heat via pressurized air or a fan/rotary mechanism, which leverages forced convection to remove heat from the heat sink to the external environment through one or more exit vents on the charging cable connector.

The charging cable connector may have charging contacts with radiative fins to enhance heat exchange by increasing the surface area of the contacts. This allows for higher heat transfer from the charging contacts to the thermal sink.

The charging cable connector may include one or more heat pipes to extract heat from the charging contacts. The heat extracted will be transferred from the source to the heat sink in the charging cable connector. A heat pipe leverages the phase change property of the thermal fluid to extract heat from the source. This will enable higher transfer of thermal load from the source and enhance overall performance.

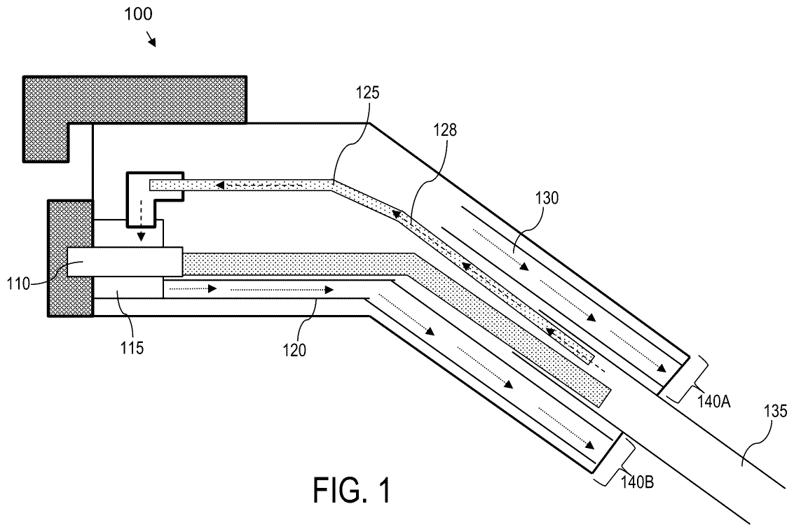

FIG. 1 shows an air cooled EV charging cable connector according to an embodiment. A pressurized air supply feeds pressurized air through the tube 125 to the manifold 115. The tube 125 is included in the charging cable 135. The manifold 115 is in contact with the charging carrying components (e.g., the charging contacts 110). The manifold 115 may include a push-to-connect pneumatic fitting and a cylindrical hollow body. The push-to-connect fitting integrates with tube 125 and directs the air in the manifold hollow body. The hollow body forms an enclosure over the charging contacts 110 and ensures that the cold pressurized air flows over the charging contacts 110. This maximizes the extraction of the heat load from the charging contacts 110. The air flow 128 is sent through the tube 125 and is directed by the manifold 115 over the charging contacts 110 thereby picking up the heat load generated during a charging session and cooling down the charging contacts 110. The pressurized air supply is external to the charging cable connector 100. The pressurized air supply may be supplied by the EVSE. After extracting the heat, the hot air exits the charging cable connector 100. The hot air exits as shown in the air flow 130 through the air exhaust vents 140A and 140B, which are shown as being at the end of the charging cable connector 100 at opposing sides of the charging cable 135. The charging cable connector 100 includes the vent channel 120 to guide the hot air to the air exhaust vents.

Although FIG. 1 shows exhaust vents on opposing sides of the charging cable, in an embodiment there may be only one set of exhaust events (e.g., on one side of the charging cable). Although FIG. 1 shows exhaust vents at the end of the charging connector 100, in an embodiment one or more exhaust vents can be located elsewhere on the charging connector (e.g., on the bottom of the charging connector 100, on the top of the charging connector 100).

Although FIG. 1 shows the hot air exhaust exiting through vents, the hot air can exit the charging connector differently. For example, in an embodiment the hot air exits through one or more return tubes that are part of the charging cable 135 and optionally one or more vents. The hot air from the return tube(s) can be exhausted to the outside environment via one or more vents in the EVSE. The charging cable connector may include air exhaust vent(s) and a return tube. In another embodiment, each power conductor within the charging cable may be placed inside its own finned tube concentrically to create an air-gap, and the hot air can flow through the air-gap within the finned tubes along the length of the charging cable, which also picks up heat from the power conductors. The hot air flowing through the air-gap can be vented to the outside environment via the EVSE.

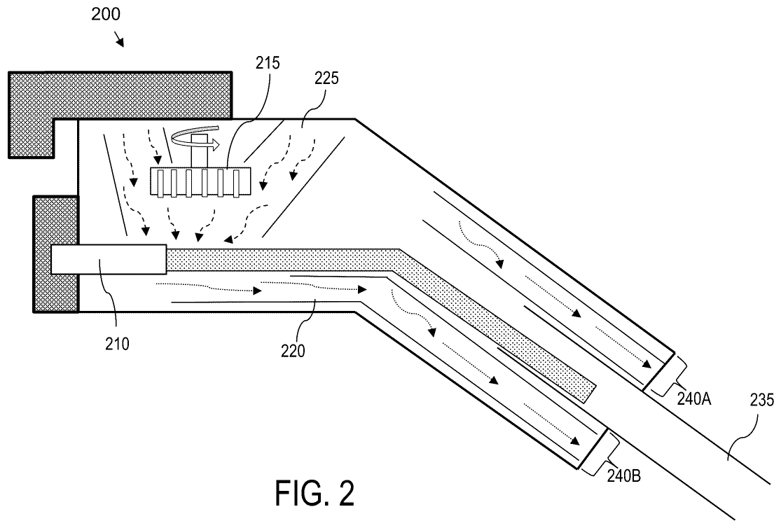

FIG. 2 shows an air cooled EV charging cable connector according to another embodiment. In FIG. 2, the charging cable connector 200 includes a fan/rotary turbine 215 that draws air from the ambient environment through one or more intake vents 225. This air is channeled to the charging carrying components (e.g., the charging contacts 210). The channeling of the air may be done with a manifold (e.g., like the manifold 115) or internal ducts. The internal ducts may be micro-ducts that target the air and increase air velocity. The air flow picks up the heat load generated during a charging session and cools down the charging contacts 210. After extracting the heat, the hot air exits the charging cable connector 200. The hot air exits through the air exhaust vents 240A and 240B, which are shown as being at the end of the charging cable connector 200 at opposing sides of the charging cable 235. The charging cable connector 200 includes the vent channel 220 to guide the hot air to the air exhaust vents.

Although FIG. 2 shows exhaust vents on opposing sides of the charging cable, in an embodiment there may be only one set of exhaust events (e.g., on one side of the charging cable). Although FIG. 2 shows exhaust vents at the end of the charging connector 200, in an embodiment one or more exhaust vents can be located elsewhere on the charging connector (e.g., on the bottom of the charging connector 200, on the top of the charging connector 200).

Although FIG. 2 shows the hot air exhaust exiting through vent(s), the hot air can exit the charging connector 200 differently. For example, in an embodiment the hot air exits through one or more return tubes that are part of the charging cable 235 and optionally one or more vents. The hot air from the return tube(s) can be exhausted to the outside environment via one or more vents in the EVSE. In another embodiment, each power conductor within the charging cable 235 may be placed inside its own finned tube concentrically to create an air-gap, and the hot air can flow through the air-gap within the finned tubes along the length of the charging cable 235, which also picks up heat from the power conductors. The hot air flowing through the air-gap can be vented to the outside environment via the EVSE.

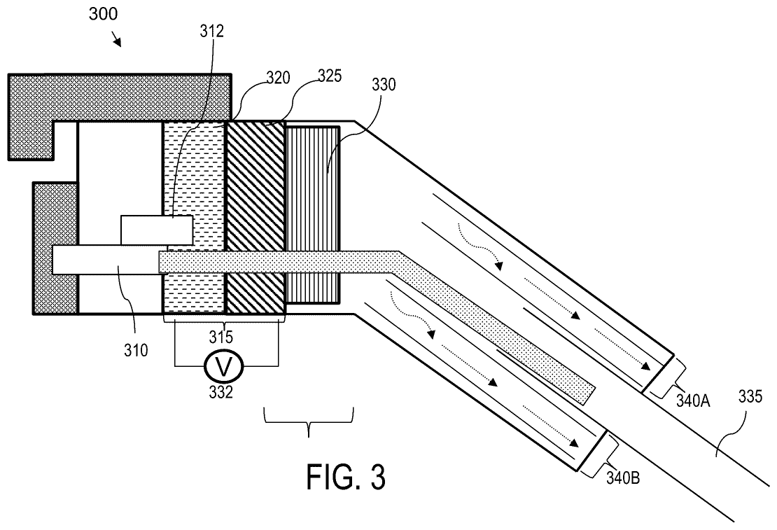

FIG. 3 shows an air cooled EV charging cable connector according to another embodiment. In FIG. 3, the charging cable connector 300 includes a thermoelectric device 315 that is used to remove heat from the charging contacts 310. When a voltage 332 is applied to the thermoelectric device 315, a temperature gradient is generated across the thermoelectric device 315. The EVSE sources the voltage 332 and power is provided to the thermoelectric device 315 via a low-voltage wire in the charging cable. The temperature gradient removes heat from the charging contacts 310. The cold end 320 of the thermoelectric device 315 is connected to the charging contacts 310 via the metal connecting bar 312. The metal connecting bar 312 is attached to the cold end 320 of the thermoelectric device using a thermal paste to maintain electrical isolation between the charging contacts 310 and the thermoelectric device 315. The cold end 320 of the thermoelectric device 315 absorbs the heat from the charging contacts 310. The hot end 325 of the thermoelectric device 315 is connected to the heat sink 330 and releases the heat into the heat sink 330. The heat sink 330 may be used to dissipate the heat via pressurized air or a fan/rotary mechanism, which leverages forced convection to remove heat from the heat sink to the external environment through one or more exit vents 340A and 340B on the charging cable connector 300. In an embodiment, one or more drain holes may be included in the charging cable connector 300 to allow any captured moisture to weep out of the charging cable connector.

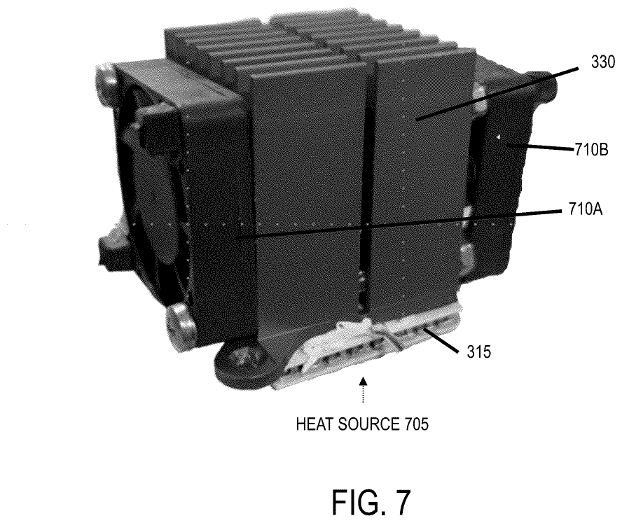

FIG. 7 shows an example thermoelectric device assembly according to an embodiment, which can be used in the embodiment shown in FIG. 3. In the example shown in FIG. 3, the heat source 705 is positioned below the thermoelectric device 315. The hot end of the thermoelectric device 315 is connected to the heat sink 330. The fans 710A and 710B that are connected to the heat sink 330 are used to extract heat away from the heat sink 330.

Although FIG. 3 shows the hot air exhaust exiting through vent(s), the hot air can exit the charging connector 300 differently. For example, in an embodiment the hot air exits through one or more return tubes that are part of the charging cable 335 and optionally one or more vents. The hot air from the return tube(s) can be exhausted to the outside environment via one or more vents in the EVSE. In another embodiment, each power conductor within the charging cable 335 may be placed inside its own finned tube concentrically to create an air-gap, and the hot air can flow through the air-gap within the finned tubes along the length of the charging cable 335, which also picks up heat from the power conductors. The hot air flowing through the air-gap can be vented to the outside environment via the EVSE.

The charging cable connector may have charging contacts with radiative fins to enhance heat exchange by increasing the surface area of the contacts. This allows for higher heat transfer from the charging contacts to the thermal sink. The charging contacts of the charging cable connectors 100, 200, and 300 may have radiative fins.

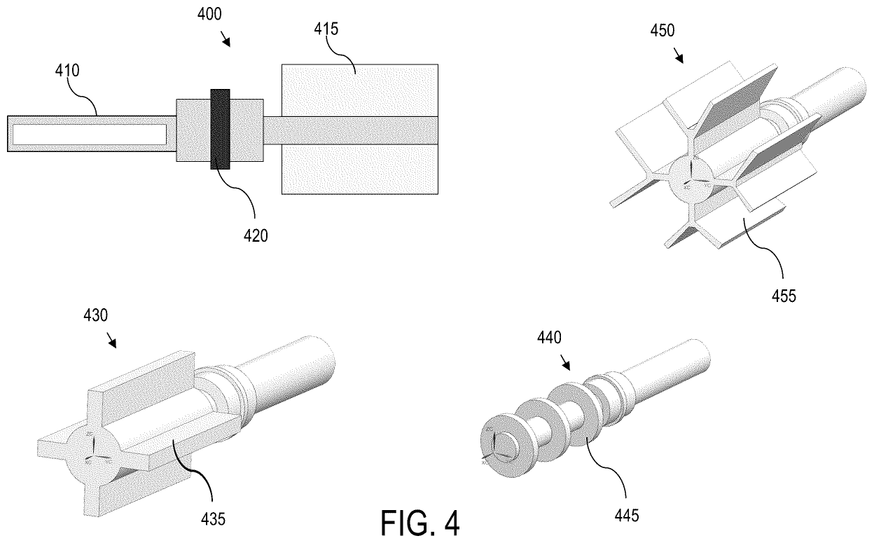

FIG. 4 shows examples of a charging contact with radiative fins according to an embodiment. The charging contact 400 includes a charging pin 410, an O-ring 420, and a radiative fin 415. The O-ring 420 provides water-ingress protection for the charging connector. The radiative fin can take different shapes and forms, and there may be one or more radiative fins. One example is the radiative fin assembly 430 that includes four rectangle shaped radiative fins 435 each at approximately 90 degrees from each other. Another example is the radiative fin assembly 440 that includes a series of ring shaped radiative fins 445. Another example is the radiative fin assembly 450 that includes the y-shaped radiative fins 455 each at approximately 90 degrees from each other.

The cable connectors 100, 200, and 300 may include one or more heat pipes to extract heat from the charging cable contacts and transfer to a heat sink. The heat pipe leverages the phase change property of the thermal fluid to extract heat from the source. This will enable higher transfer of thermal load from the source and enhance overall performance.

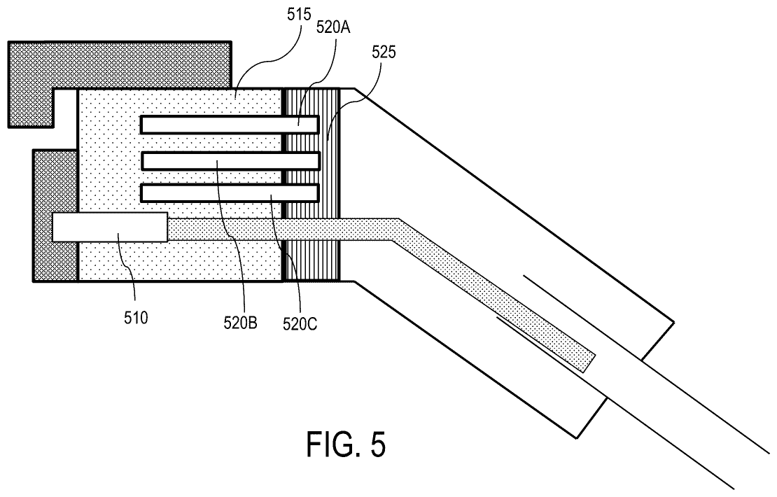

FIG. 5 illustrates an example heat pipe configuration according to an embodiment. In the example of FIG. 5, the heat pipe(s) are not integrated directly with the charging contacts. The heat pipes 520A, 520B, and 520C are installed on the thermal epoxy 515. The thermal epoxy 515 and the heat pipes 520A-520C absorb heat from the charging contacts 510 and transfer the heat to the heat sink 525. Although three heat pipes are shown in FIG. 5, there may be more, or fewer, heat pipes in some embodiments.

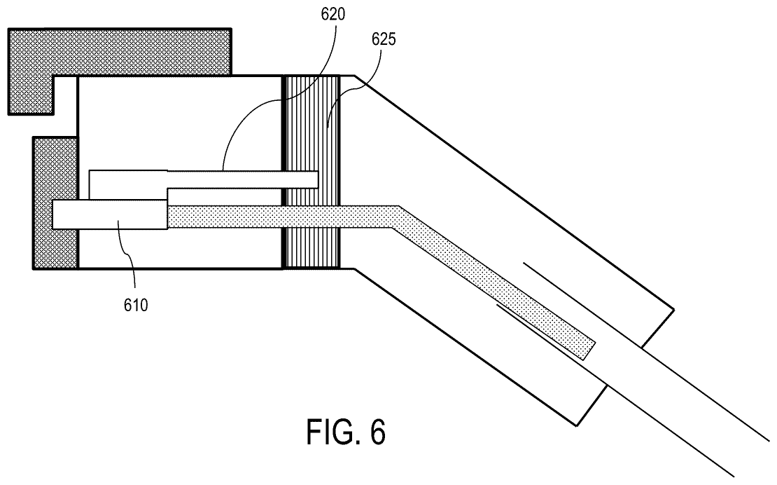

FIG. 6 illustrates another example heat pipe configuration according to an embodiment. In the example of FIG. 6, a heat pipe 620 is integrated directly with the charging contacts 610. Thermal grease can be used to bond the heat pipe 620 with the charging contacts 610, thereby creating an electrical isolation. The heat pipe 620 absorbs heat directly from the charging contacts 610 and transfers the heat to the heat sink 625.

The heat pipe configurations shown in FIGS. 5 and 6 can be used to extract heat from the charging contacts using a pressurized air source (e.g., as described in FIG. 1), or without using a pressurized air source (e.g., as described in FIG. 1), using a fan/rotary (e.g., as described in FIG. 2), or without using a fan/rotary (e.g., as described in FIG. 2).

In an embodiment, the charging cable is cooled using forced air. In such an embodiment, air is fed within the cable via the electric vehicle charging system (e.g., by a compressed air sub-system in the EVSE or connected to the EVSE, and/or fans in the EVSE or connected to the EVSE). The charging cable may include one or more feed tubes that carry the forced air from the charging system to the charging connector. The forced air picks up heat from the charging connector and the heated air exits either in the charging connector or via the charging cable.

Each power conductor within the charging cable may be placed inside its own finned tube concentrically. This allows for an air-gap between the power conductors and the finned tubes, where air can be fed through the air-gap and flow over the power conductors to enable heat transfer from the power conductors to the external environment. For example, the forced air picks up heat from the charging connector and then is directed (e.g., via the use of a manifold which can be a metal enclosure with fittings) through the air-gap within the finned tubes throughout the length of the cable. The air picks up heat from the charging connector and the cable and becomes hot in the process due to heat transfer. The heated air is then vented to the outside environment via the EVSE. The finned tube geometry helps in enhancing the heat transfer by increasing air-flow local turbulence. The finned tube structure also helps in constraining the power conductors concentrically to ensure a symmetric air-gap is maintained throughout the length of the cable. The air flowing through the air gap of the finned tubes is expected to be at a lower temperature than the power conductors and thus will pick up heat from the power conductors that is vented to the outside environment via the EVSE.

In an embodiment, the charging cable is cooled using a sub-ambient cooling system. The sub-ambient cooling system, which is a closed-loop system and can be integrated into the EVSE or connected to the EVSE, passes cold refrigerant gases (e.g., CO2, Nitrogen, Helium) in the feed tubes. The sub-ambient refrigerant gas will pick up heat and enable heat transfer from the heat loads (e.g., the charging contacts and the power conductors) on the return path as it passes over the charging connector and the power conductors (e.g., through the air-gaps).

In an embodiment, a heat exchanger is integrated between a sub-ambient cooling system and a forced air system (a fan or compressor) to cool the charging cable. The heat exchanger cools the air to temperatures below ambient, enhancing its cooling capacity. The cold air is fed through the feed tubes, picking up the heat on the return path. After picking up the heat from the cable and the connector, the hot air can be vented to the atmosphere.

In an embodiment, the charging cable is cooled using a phase change material that is between the power conductors and the tube enclosing the power conductor. Upon delivery of power through the power conductors, the heat generated by the power conductors is conducted to the phase change material. The phase change material absorbs the heat and changes the phase either from solid to liquid or liquid to gas, depending on the operating condition of the charging cable and temperature. The process of phase change leverages latent heat capacity of the material. During this process, the temperature of the phase change material stays constant until the phase has completely changed from either solid to liquid or liquid to gas. This enables the charging cable to be able to operate longer at peak power without increasing the surface temperature of the cable. The enables a high-power, low-cost solution in comparison with liquid cooled and air-cooled cables. The phase change materials may be selected from a category of hydrated salts, organic compounds such as paraffin or fatty acids, and polymers. Feed tube(s) in the charging cable may be used to deliver air to the charging connector and the heated air may be vented from the charging connector to the environment. As an alternative, if the connector has a fan/rotary turbine (e.g., like the connector 200), feed tube(s) may not be included in the charging cable and the heated air may be vented from the charging connector to the environment.

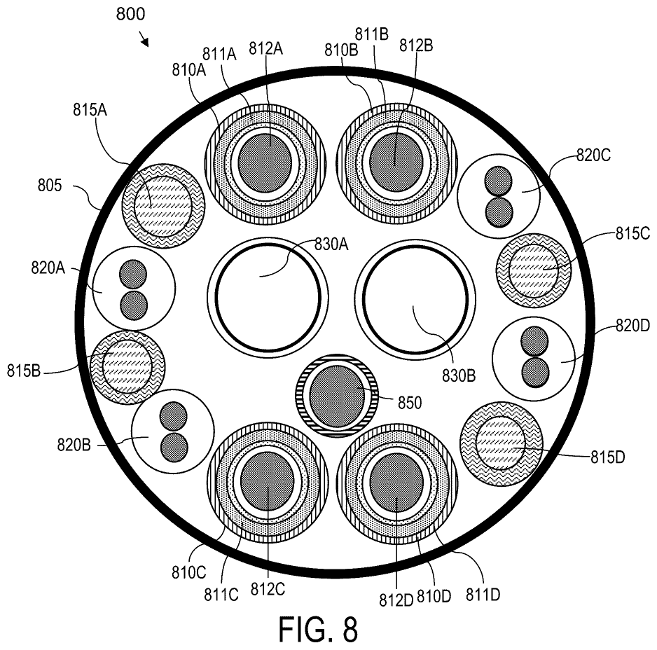

FIG. 8 shows a cross-section of an example charging cable 800 according to an embodiment. The charging cable 800 can be used with any of the connectors described herein (e.g., the connector 100, the connector 200, the connector 300) or otherwise any of the cooling techniques described herein. The charging cable 800 can also be used without any of the connectors described herein.

The charging cable 800 includes the cable jacket 805. The cable jacket 805 protects the internal components of the charging cable 800 from environmental factors and mechanical stresses. The cable jacket 805 can be made from UL62 EV or EVE materials. Within the cable are power conductors, one or more signal conductors, a ground conductor, and one or more feed tubes.

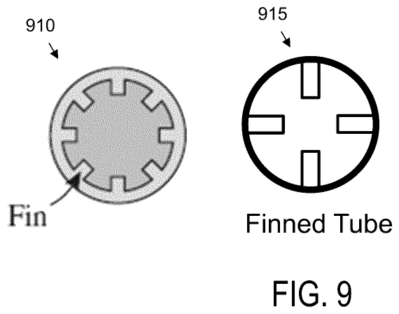

The charging cable 800 includes power conductors that include the power conductor cores 812A, 812B, 812C, and 812D, which are placed concentrically inside the finned tubes 810A, 810B, 810C, and 810D respectively. This creates an air-gap 811A, 811B, 811C, and 811D between the power conductor cores 812A-D and the finned tubes 810A-D respectively. FIG. 9 illustrates exemplary finned tube structures according to an embodiment. The finned tube structure 910 and the finned tube structure 915 each include a number of fins that allow for a power conductor core to be placed concentrically within the finned tube thereby creating an air-gap.

In an embodiment where forced air is used, the return air is passed through the air-gaps 811A-811D over the power conductor cores 812A-812D, which picks up heat from the power conductor cores 812A-811D which is then exited to the external environment. In an embodiment where a sub-ambient cooling system is used, the air-gaps 811A-811D carry the return sub-ambient refrigerant gas over the power conductor cores 812A-812D, which picks up heat from the power conductor cores 812A-812D. In an embodiment where a heat exchanger is integrated between a sub-ambient cooling system and a forced air system, sub-ambient air is passed through the air-gaps 811A-811D over the power conductor cores 812A-812D, which picks up heat from the power conductor cores 812A-812D which is then exited to the external environment.

In an embodiment where a phase change material is used, the phase change material is added in the air-gaps 811A-811D. Upon delivery of power through the power conductor cores 812A-812D, the heat generated by the power conductors will be conducted to the phase change material. The phase change material will absorb the heat and change phase either from solid to liquid or liquid to gas, depending on the operating condition of the charging cable and temperature.

The charging cable 800 further includes the signal conductors 820A-820D. The signal conductors are used for communication, safety, and control between the EVSE and the electric vehicle. These may include a control pilot signal conductor and a proximity pilot signal conductor. The signal conductors can also be used to support one or more devices on the charging connector such as a thermoelectric device and/or a fan/rotary.

The charging cable 800 further includes the ground conductor 850. The charging cable 800 further includes the cable fillers 815A, 815B, 815C, and 815D. The cable fillers 815A-D help keep the cable uniform by preventing gaps between the conductors and the jacket. The cable fillers 815A-D can be made from plastic, such as Plastic, such as polypropylene or polyethylene. The number and size of the cable fillers can be different from what is shown in FIG. 8.

The charging cable 800 further includes the feed tubes 830A and 830B. In an embodiment where forced air is used, the feed tubes 830A and 830B are used for carrying the forced air from the charging system to the charging connector. In an embodiment where a sub-ambient cooling system is used, the feed tubes 830A and 830B are used for carrying cold refrigerant gases (e.g., CO2, Nitrogen, Helium). In an embodiment where a heat exchanger is integrated between a sub-ambient cooling system and a forced air system, the feed tubes 830A and 830B are used for carrying cold (sub-ambient) air. In an embodiment where phase change material is used, the feed tubes 830A and 830B are used to carry air to the charging connector and the heated return air is vented from the charging connector to the environment. Although two feed tubes are shown, the number of feed tubes is exemplary as there may be fewer (i.e., one feed tube) or more feed tubes.

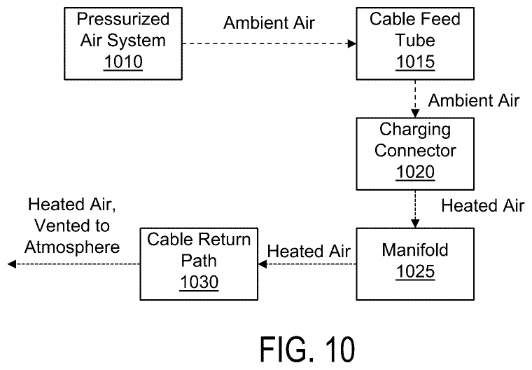

FIG. 10 shows a system for cooling the charging cable using forced air, according to an embodiment. The pressurized air system 1010, which can be a compressor system and/or fans, delivers ambient air through the cable feed tube 1015. The cable feed tube 1015 can represent the feed tubes 830A and/or 830B shown in FIG. 8. The pressurized ambient air is carried through the cable feed tube 1015 to the charging connector 1020, which is a heat load. The charging connector 1020 can take the form of the connector 100, the connector 200, or the connector 300. The ambient air picks up heat from the charging connector 1020 and the heated air is directed, via the manifold 1025, to the cable return path 1030. The cable return path 1030, which is a heat load, includes the air-gaps between the power conductors and the finned tubes where the heated air is fed through the air-gaps and flows over the power conductors to enable heat transfer from the power conductors to the external environment. The heated air is then vented to the outside environment via the EVSE. As an alternative to a cable return path, the return path of the heated air can exit the charging connector itself.

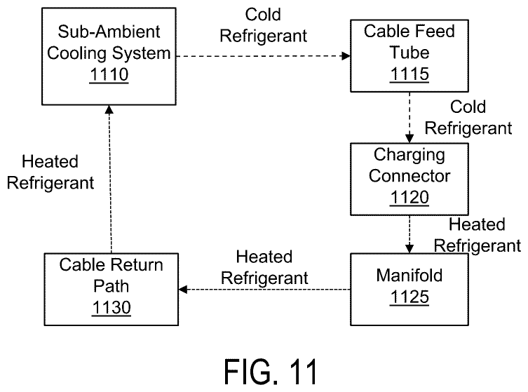

FIG. 11 shows a system for cooling the charging cable using a sub-ambient cooling system, according to an embodiment. The sub-ambient cooling system 1110 is a closed-loop system that can be integrated into the EVSE or connected to the EVSE. The sub-ambient cooling system 1110 passes cold (sub-ambient) refrigerant gases (e.g., CO2, Nitrogen, Helium) in the cable feed tube 1115. The cable feed tube 1115 can represent the feed tubes 830A and/or 830B shown in FIG. 8. The sub-ambient refrigerant gas is carried through the cable feed tube 1115 to the charging connector 1120, which is a heat load. The charging connector 1120 can take the form of the connector 100, the connector 200, or the connector 300. The sub-ambient refrigerant gas picks up heat from the charging connector 1120 and the heated refrigerant gas is directed, via the manifold 1125, to the cable return path 1130. The cable return path 1130, which is a heat load, includes the air-gaps between the power conductors and the finned tubes where the heated refrigerant is fed through the air-gaps and flows over the power conductors to enable heat transfer from the power conductors. The heated refrigerant is returned to the sub-ambient cooling system 1110.

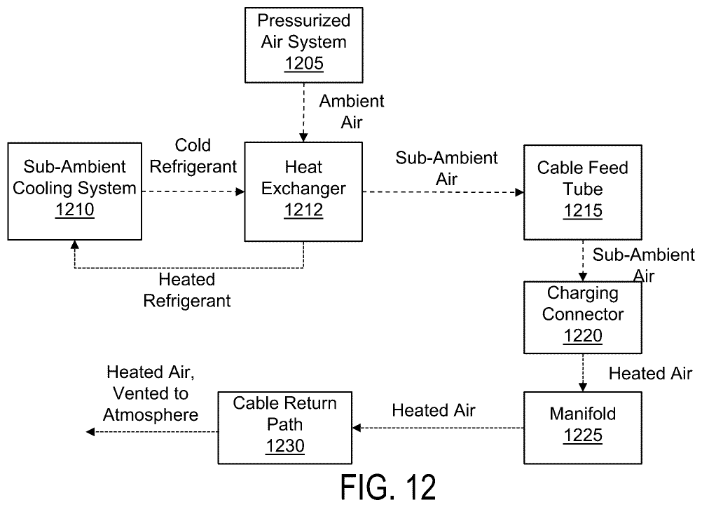

FIG. 12 shows a system for cooling the charging cable where a heat exchanger is integrated between a sub-ambient cooling system and a forced air system to cool the charging cable, according to an embodiment. The heat exchanger 1212 is integrated between the sub-ambient cooling system 1210 and the pressurized air system 1205. The sub-ambient cooling system 1110 is a closed-loop system with the heat exchanger 1212. The sub-ambient cooling system 1110 feeds cold (sub-ambient) refrigerant gases (e.g., CO2, Nitrogen, Helium) to the heat exchanger 1212. The pressurized air system 1205, which can be a compressor system and/or fans, delivers ambient air to the heat exchanger 1212. The cold refrigerant supplied by the sub-ambient cooling system 1210 cools the ambient air supplied by the pressurized air system 1205, which causes the cold refrigerant to be heated. The heated refrigerant is returned to the sub-ambient cooling system 1210. The sub-ambient air from the heat exchanger 1212 is carried through the cable feed tube 1215. The cable feed tube 1215 can represent the feed tubes 830A and/or 830B shown in FIG. 8. The sub-ambient air is carried through the cable feed tube 1215 to the charging connector 1220, which is a heat load. The charging connector 1220 can take the form of the connector 100, the connector 200, or the connector 300. The sub-ambient air picks up heat from the charging connector 1220 and the heated air is directed, via the manifold 1225, to the cable return path 1230. The cable return path 1230, which is a heat load, includes the air-gaps between the power conductors and the finned tubes where the heated air is fed through the air-gaps and flows over the power conductors to enable heat transfer from the power conductors to the external environment. The heated air is then vented to the outside environment via the EVSE. As an alternative to a cable return path, the return path of the heated air can exit the charging connector itself.

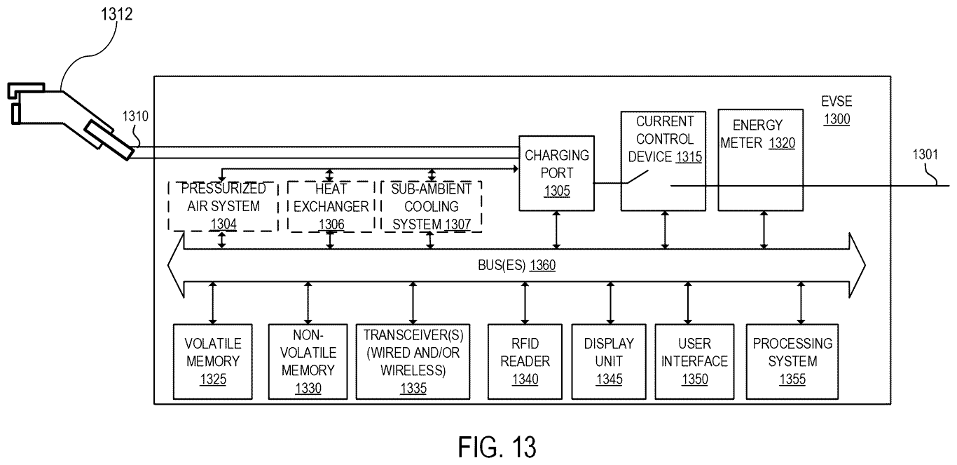

FIG. 13 shows an exemplary embodiment of an electric vehicle supply equipment (EVSE), sometimes called an EV charging station, according to an embodiment. As illustrated in FIG. 13, the EVSE 1300 includes the charging port 1305, the current control device 1315, the energy meter 1320, the volatile memory 1325, the non-volatile memory 1330 (e.g., hard drive, flash, PCM, etc.), one or more transceiver(s) 1335 (e.g., wired transceiver(s) (e.g., Ethernet, power line communication (PLC), etc.) and/or wireless transceiver(s) (e.g., 1302.15.4 (e.g., ZigBee, etc.), RF, Bluetooth, Wi-Fi, Infrared, GPRS/GSM, CDMA, etc.)), the RFID reader 1340, the display unit 1345, the user interface 1350, and the processing system 1355 (e.g., one or more microprocessors and/or a system on an integrated circuit), which may be coupled with one or more buses 1360.

The charging port 1305 is a power receptacle (e.g., for receiving a charging cable plug), circuitry for an attached charging cord cable, or circuitry for wireless charging. While FIG. 13 illustrates a single charging port 1305, the EVSE 1300 may include multiple charging ports which may be the same or different types. One end of a charging cable 1310 connects to the charging port 1305 and the other end connects to an electric vehicle through a charging cable connector 1312. The charging cable connector 1312 may take the form of the cable connector 100, the cable connector 200, or the cable connector 300.

In an embodiment that uses pressurized air, the EVSE 1300 includes the pressurized air system 1304. The pressurized air system 1304 feeds pressurized air through a feed tube of the charging cable 1310. The pressurized air system 1304 may supply pressurized air responsive to a charging session beginning. The charging cable 1310 may include one or more return tubes to carry the hot air, which can then be vented by the EVSE 1300 to the external environment. The charging cable 1310 may include finned tubes to carry the hot air and cool the power conductors, and the EVSE 1300 can vent the hot air to the external environment.

In an embodiment that uses a sub-ambient cooling system, the EVSE 1300 may include the sub-ambient cooling system 1307. The sub-ambient cooling system passes cold refrigerant gases (e.g., CO2, Nitrogen, Helium) in the feed tube(s) of the charging cable 1310. The sub-ambient refrigerant gas will pick up heat and enable heat transfer from the heat loads (e.g., the charging contacts and the power conductors) on the return path as it passes over the charging connector and the power conductors (e.g., through the air-gaps).

In an embodiment that uses a heat exchanger, the EVSE 1300 may include the heat exchanger 1306. The heat exchanger 1306 may be integrated between the sub-ambient cooling system 1307 and the pressurized air system 1304 to cool the charging cable. The heat exchanger 1306 cools the air to temperatures below ambient, enhancing its cooling capacity. The cold air is fed through the feed tube(s) of the charging cable 1310, picking up the heat on the return path. After picking up the heat from the cable 1310 and the connector 1312, the hot air can be vented to the atmosphere.

The current control device 1315 controls the current flowing on the power line 1301. For example, in some embodiments the current control device 1315 energizes the charging port 1305 (e.g., by completing the circuit to the power line 1301) or de-energizes the charging port 1305 (e.g., by breaking the circuit to the power line 1301). The current control device 1315 may be a set of contactors. In some embodiments the current control device 1315 energizes the charging port 1305 responsive to receiving a command from a server that indicates charging is authorized.

The energy meter 1320 measures the amount of electricity that is flowing on the power line 1301 through the charging port 1305. While in one embodiment the energy meter 1320 measures current flow, in an alternative embodiment the energy meter 1320 measures power draw. The energy meter 1320 may be an induction coil or other devices suitable for measuring electricity. While the energy meter 1320 is illustrated as being included within the EVSE 1300, in other embodiments the energy meter 1320 is exterior to the EVSE 1300 but capable of measuring the amount of electricity flowing on the power line 1301 through the charging port 1305.

The RFID reader 1340 reads RFID tags from RFID enabled devices (e.g., smartcards, key fobs, contactless credit cards, etc.), embedded with RFID tag(s) of operators that want to use the EVSE 1300. For example, in some embodiments a vehicle operator can wave/swipe an RFID enabled device near the RFID reader 1340 to provide an access credential for use of the EVSE 1300.

The transceiver(s) 1335 transmit and receive messages. For example, the transceiver(s) 1335 may transmit authorization requests to the EV charging network server, receive commands from the EV charging network server indicating whether the charging session is authorized, etc. The transceiver(s) 1335 may include an RF transmitter that can trigger the opening of a charging port door of an electric vehicle inlet as described herein.

The display unit 1345 is used to display messages to vehicle operators including charging status, confirmation messages, error messages, notification messages, etc. The user interface 1350 allows operators to interact with the EVSE 1300. By way of example, the user interface 1350 allows electric vehicle operators to present an access credential, enter in account and/or payment information, etc.

The processing system 1355 may retrieve instruction(s) from the volatile memory 1325 and/or the non-volatile memory 1330 and execute the instructions to perform operations for the electric vehicle charging station.

Although several components are illustrated as being included in the EVSE 1300, in some embodiments additional, different, or less components may be used in the EVSE 1300. For example, some EVSEs may not include a display or a user interface. Other EVSEs may not include an RFID reader or an energy meter. Other EVSEs may include one or more lights that can provide visual indications.

What is claimed is:

1. A cooling system for electric vehicle (EV) charging heat loads, comprising:
a pressurized air system for delivering ambient air, the pressurized air system including at least one of a compressor system and a set one or more fans;
a charging cable that includes:
a plurality of power conductors, each concentrically placed inside a corresponding finned tube, thereby creating an air gap between each power conductor and its corresponding finned tube, and
a cable feed tube that carries the ambient air from the pressurized air system to an EV charging cable connector attached to the charging cable to cool a set of one or more charging contacts;
wherein the EV charging cable connector includes:
the set of one or more charging contacts, and
a manifold that directs the ambient air carried through the cable feed tube over the set of one or more charging contacts and through each air gap between each power conductor and its corresponding finned tube.

2. The cooling system for EV charging heat loads of claim 1, wherein the manifold is contact with the set of one or more charging contacts.

3. The cooling system for EV charging heat loads of claim 1, wherein the set of one or more charging contacts each includes at least one radiative fin.

4. The cooling system for EV charging heat loads of claim 3, wherein the at least one radiative fin is rectangular shaped.

5. The cooling system for EV charging heat loads of claim 3, wherein the at least one radiative fin is ring shaped.

6. The cooling system for EV charging heat loads of claim 3, wherein the at least one radiative fin is y-shaped.

7. The cooling system for EV charging heat loads of claim 1, wherein the EV charging cable connector further comprises:
a heat sink; and
one or more heat pipes directly connected to the set of one or more charging contacts, the one or more heat pipes to transfer heat from the set of one or more charging contacts to the heat sink.

8. The cooling system for EV charging heat loads of claim 1, wherein the EV charging cable connector further comprises:
a heat sink;
a thermal epoxy connected to the set of one or more charging contacts; and
one or more heat pipes connected to the thermal epoxy, the one or more heat pipes to transfer heat from the set of one or more charging contacts to the heat sink.

9. The cooling system for EV charging heat loads of claim 1, wherein the pressurized air system is located within an electric vehicle supply equipment (EVSE), and wherein the ambient air flowing through each air gap is vented to an external environment via the EVSE.

10. The cooling system for EV charging heat loads of claim 1, wherein the manifold comprises a hollow body that forms an enclosure over the set of one or more charging contacts.

11. A method for cooling electric vehicle (EV) charging heat loads, comprising:
delivering ambient air using a pressurized air system, the pressurized air system including at least one of a compressor system and a set of one or more fans;
carrying the ambient air through a cable feed tube within a charging cable to an EV charging cable connector attached to the charging cable; and
directing, via a manifold included in the EV charging cable connector, the ambient air carried through the cable feed tube over a set of one or more charging contacts and through a plurality of air gaps within the charging cable, wherein each air gap is formed between a power conductor of the charging cable and a corresponding finned tube in which the power conductor is concentrically placed.

12. The method of claim 11, wherein the manifold is in contact with the set of one or more charging contacts.

13. The method of claim 11, wherein the set of one or more charging contacts each includes at least one radiative fin.

14. The method of claim 13, wherein the at least one radiative fin is rectangular shaped.

15. The method of claim 13, wherein the at least one radiative fin is ring shaped.

16. The method of claim 13, wherein the at least one radiative fin is y-shaped.

17. The method of claim 11, further comprising transferring heat from the set of one or more charging contacts to a heat sink using one or more heat pipes directly connected to the set of one or more charging contacts.

18. The method of claim 11, further comprising transferring heat from the set of one or more charging contacts to a heat sink using one or more heat pipes connected to a thermal epoxy, wherein the thermal epoxy is connected to the set of one or more charging contacts.

19. The method of claim 11, further comprising venting the ambient air flowing through the plurality of air gaps to an external environment via an electric vehicle supply equipment (EVSE).

20. The method of claim 11, wherein the manifold includes a hollow body forming an enclosure over the set of one or more charging contacts, and wherein directing the ambient air comprises flowing the ambient air through the hollow body over the set of one or more charging contacts.
